(19) United States
(12) Patent Application Publication
(10) Pub. No.: US 2026/0231355 A1
(43) Pub. Date: Aug. 6, 2026

(54) WICKING MITIGATION VIA NOTCHES AND DIMPLES

(71) Applicant: DELL PRODUCTS L.P., Round Rock, TX (US)

(72) Inventors: Patrick Illingworth, Austin, TX (US); Robert Johnson, Round Rock, TX (US); Liang-Chun Ma, Taoyuan City (TW)

(21) Appl. No.: 19/043,689

(22) Filed: Feb. 3, 2025

(51) Int. Cl. H05K 7/20; G06F 1/20

(52) U.S. Cl. CPC H05K 7/20218; G06F 1/20

(57) ABSTRACT

A wicking mitigation chassis for housing components of a liquid-cooled information handling system includes one or more notches formed in an edge of a bottom of the chassis. The one or more notches are configured to disrupt a flow of fluid within the chassis caused by leakage from a liquid cooling subassembly housed within the chassis to slow wicking of the fluid. The wicking mitigation chassis includes one or more rises in an outer surface of the bottom of the chassis created by dimpling an opposing surface of the bottom of the chassis. The one or more rises are configured to concentrate at least a portion of the flow of fluid in regions of the outer surface surrounding the one or more rises.

### FIELD OF THE DISCLOSURE

The present disclosure generally relates to information handling systems, and more particularly relates to leak mitigation in liquid-cooled information handling systems.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A wicking mitigation chassis to house components of a liquid-cooled information handling system includes one or more notches formed in an edge of a bottom of the chassis. The one or more notches are configured to disrupt a flow of fluid within the chassis caused by leakage from a liquid cooling subassembly housed within the chassis to thereby slow wicking of the fluid. The wicking mitigation chassis includes one or more rises in an outer surface of the bottom of the chassis created by dimpling an opposing surface of the bottom of the chassis. The one or more rises are configured to concentrate at least a portion of the flow of fluid in regions of the outer surface surrounding the one or more rises.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is perspective view of a portion of a wicking mitigation chassis to house components of a liquid-cooled information handling system according to an embodiment of the present disclosure;

FIG. 2 is a perspective view of the underside of a bottom portion of a wicking mitigation chassis according to an embodiment of the present disclosure;

FIG. 3 is another perspective view of the underside of a bottom portion of a wicking mitigation chassis according to an embodiment of the present disclosure;

FIG. 4 is a flow diagram of a method for mitigating fluid wicking within a chassis of a liquid-cooled information handling system; and

FIG. 5 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

For purposes of this disclosure, an information handling system is one that includes a liquid cooling apparatus or subassembly. Such an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, such an information handling system may be a computer, server (such as a blade server or rack server), a network storage device, or any other such device and may vary in size, shape, performance, functionality, and price. The information handling system may include random access memory (RAM), one or more processing resources such as a central processing unit (CPU) or hardware or software control logic, graphics processing unit (GPU), hardware and/or software control logic, as well as ROM and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

As the processing power of information handling systems continues to increase, the use of liquid cooling is expected to become more common owing to certain advantages that liquid cooling offers over other types of cooling. A liquid cooling system typically includes a pump, radiator, reservoir, and cold plates connected via tubing that circulates coolant within the chassis of an information handling system. The coolant circulates in a closed loop within the chassis, transferring heat away from critical components of the information handling system.

Notwithstanding the advantages of liquid cooling, there is the possibility that one or more components of the liquid cooling system may develop leaks over time due to vibration, thermal cycles, aging, misalignment of heat exchangers or cold blocks, or the like. Any leak that exposes the components of the information handling system to liquid can cause corrosion or damage to the circuitry within the system's housing. In certain arrangements, a leak occurring in one information handling system also may damage one or more nearby information handling systems if the systems are sufficiently close to one another. For example, a leak may occur in one of multiple servers stacked on a vertical rack (an increasingly common configuration). As leaked coolant builds up in one information handling system on the vertical rack, there is an increasing risk that the leaked coolant may overflow and damage other information handling systems lower on the vertical rack.

It is not uncommon for low-volume, low-flow coolant leakage within the chassis of certain liquid-cooled information handling systems (e.g., rack servers) to be drawn to or wick toward the rear of the chassis in a gap created between the chassis and fan bracket. With a 2-node-in-10U (One-Unit) server, for example, fluid may wick along an edge from the Integrated Management Module (IMM) to a bus bar, posing grave risk to an entire server rack.

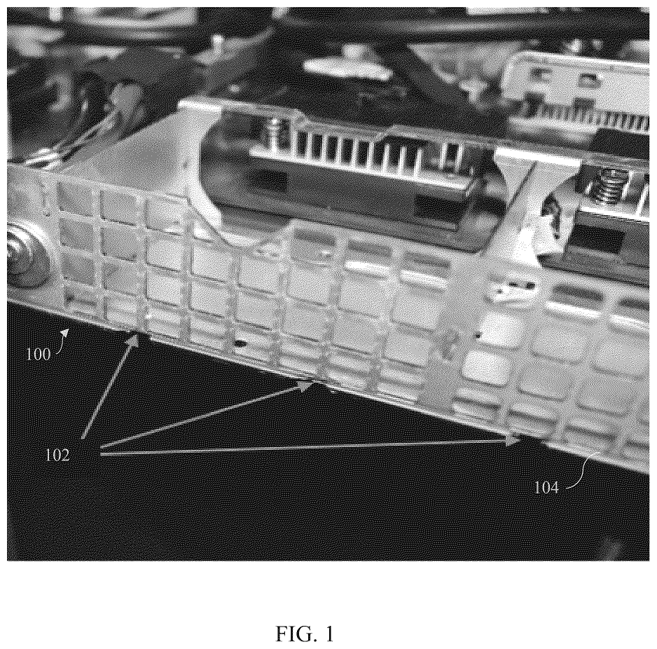

FIG. 1 is a perspective rear view of wicking mitigation chassis 100 for housing the internal components of a liquid-cooled information handling system according to certain embodiments of the present disclosure. One or more notches 102 are formed along edge 104 of the bottom of wicking mitigation chassis 100. Each notch creates a gap along edge 104. In the event that a flow of fluid is caused by leakage from a liquid cooling subassembly within wicking mitigation chassis 100, each gap slows the wicking of the fluid. Each gap created by a notch forms multiple bends along edge 104. By adding bends, each of one or more notches 102 increases the distance the fluid must traverse wicking along edge 104. For example, if the bus bar is positioned at the rear of wicking mitigation chassis 100 and the fluid wicks toward the rear, then notches 102 disrupt the flow of fluid and slow the wicking of the fluid toward the bus bar.

Additionally, one or more knobs or rises may be formed in an outer surface of the bottom of wicking mitigation chassis 100. Each knob or rise may be created, for example, by dimpling or depressing the opposing surface of the bottom of wicking mitigation chassis 100 using a press or other hydraulic tool. Each knob or rise formed in the outer surface of the bottom of wicking mitigation chassis 100 is configured to concentrate at least a portion of the flow of fluid in regions of the outer surface surrounding the knob or rise. Each knob or rise provides a point on the outer surface for fluid to gather and drip off wicking mitigation chassis 100. As fluid drips off wicking mitigation chassis 100, the amount of fluid flowing is reduced. Thus, if fluid (coolant) leaked from the liquid cooling subassembly wicks toward the bus bar at the rear of wicking mitigation chassis 100, then the one or more knobs or rises formed by dimpling eliminates or mitigates the amount of fluid wicking toward the bus bar.

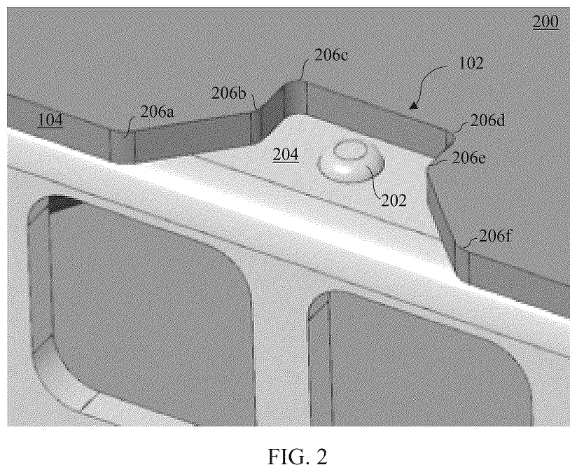

FIG. 2 is a perspective view of the underside of wicking mitigation chassis 100. Illustratively, notch 102 is formed in layer 200 along edge 104 of the bottom of wicking mitigation chassis 100 and rise 202 is formed in layer 204 of the bottom of wicking mitigation chassis 100. As shown in FIG. 2, in certain embodiments, rise 202 may be substantially centered within notch 102 formed along edge 104 of the bottom of wicking mitigation chassis 100. Substantially centered within notch 102, rise 202 is more likely to collect fluid wicking along the multiple bends created by the notch. Rise 202 concentrates all or portions of the fluid and allows the fluid to drip off wicking mitigation chassis 100. Again, for example, if fluid (coolant) leaked from the liquid cooling subassembly is wicking toward the bus bar at the rear of wicking mitigation chassis 100, then fluid dripping from rise 202 eliminates or mitigates the amount of fluid wicking toward the bus bar.

In various embodiments, the number of bends along edge 104 created by each of one or more notches 102 may vary. For example, a V-shaped notch creates only two, but in other embodiments more bends may be created. Illustratively, in FIG. 2, notch 100 creates six bends 206a, 206b, 206c, 206d, 206e, and 206f along edge 104 of wicking mitigation chassis 100.

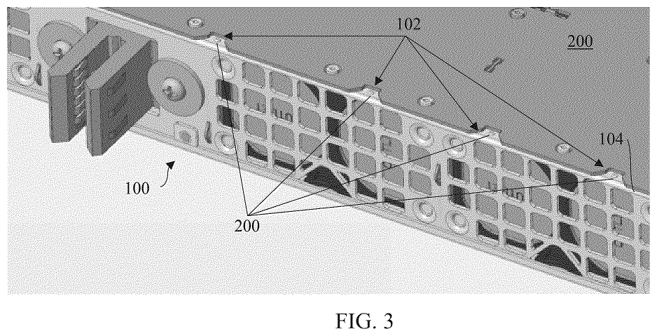

FIG. 3 is another perspective view of the underside of wicking mitigation chassis 100. Illustratively, multiple rises 200 are formed in the outer surface of the bottom of wicking mitigation chassis 100. Each knob or rise is substantially centered within notches 102 formed along edge 104, each notch forming six bends along the edge of the bottom portion of wicking mitigation chassis 100

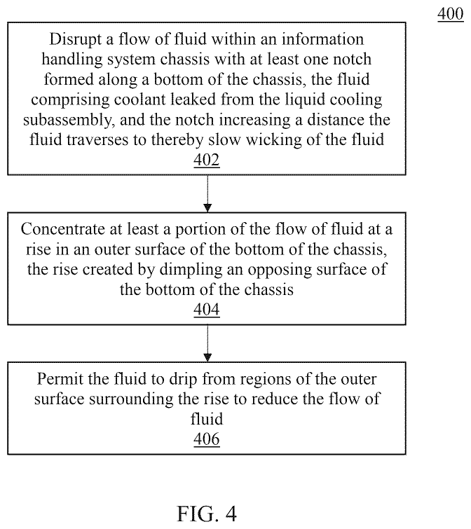

FIG. 4 is a flow diagram of example method 400 for mitigating fluid wicking in the chassis of a liquid-cooled information handling system according to an embodiment of the present disclosure. It will be readily appreciated that not every method step set forth in this flow diagram is always necessary, and that certain steps of the methods may be combined, performed simultaneously, in a different order, or perhaps omitted, without varying from the scope of the disclosure. Method 400 may be performed by a wicking mitigation chassis having certain features of wicking mitigation chassis 100 described with reference to FIGS. 1-3.

At block 402, a flow of fluid within the chassis is disrupted by one or more notches formed along an edge of the bottom of the chassis. The fluid is a coolant leaked from the liquid cooling subassembly housed within the chassis. The one or more notches increases a distance the fluid traverses to thereby slow wicking of the fluid within the chassis.

At block 404, all or a portion of the flow of fluid is concentrated at one or more rises formed in an outer surface of the bottom of the chassis, and at block 404 the fluid collected in regions surrounding each of the one or more rises is permitted to drip from the chassis to thereby reduce the flow of fluid. If the flow of fluid is wicking toward the bus bar at the rear of the chassis, then, with the notches and rises formed along the rear of the chassis bottom, dripping the fluid from the chassis eliminates or mitigates the amount of fluid wicking toward the bus bar.

In certain embodiments, the one or more notches make up multiple, spaced-apart notches formed along the edge of the bottom of the chassis. Additionally, the one or more rises may make up multiple rises formed in the outer surface of the bottom of the chassis. The spaced-apart notches may be formed in an edge of a first layer of the bottom of the chassis, the multiple rises are formed in an outer surface of a second layer of the bottom of the chassis. In certain embodiments, each of the multiple rises may be approximately centered within a respective one of the multiple, spaced-apart notches. Each notch formed along the edge of the bottom of the chassis creates multiple bends along the edge of the first layer to increase the distance that the fluid flow traverses. For example, each notch may create six or more bends along the edge of the chassis.

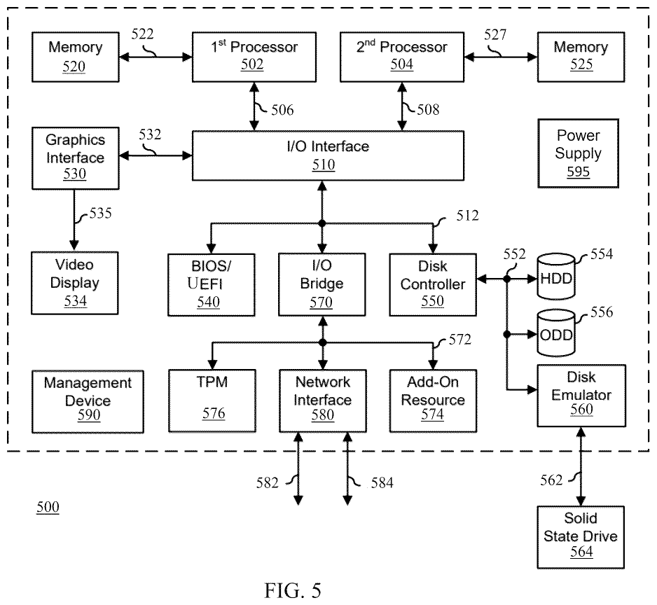

FIG. 5 shows a generalized embodiment of an information handling system 500 according to an embodiment of the present disclosure. Information handling system 500 may be substantially similar to a liquid-cooled information handling system whose components are housed within a wicking prevention chassis such as that described with reference to FIGS. 1-3. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a computer, a network server, a network storage device, a switch router or other network communication device, or any other suitable device sufficiently sized to accommodate a liquid cooling apparatus or system and which may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable mediums for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 564, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 564, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532 and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 4394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512 or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500.

Management device 590 can operate off a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

That which is claimed is:

1. A chassis of a liquid-cooled information handling system, the chassis comprising:
at least one notch formed in an edge of a bottom of the chassis, wherein the notch is configured to disrupt a flow of fluid within the chassis caused by leakage from a liquid cooling subassembly within the chassis and to slow wicking of the fluid; and
at least one rise in an outer surface of the bottom of the chassis, wherein the rise is created by dimpling an opposing surface of the bottom of the chassis and wherein the rise is configured to concentrate at least a portion of the flow of fluid in regions of the outer surface surrounding the rise.

2. The chassis of claim 1, wherein the at least one notch comprises a plurality of spaced-apart notches formed in the edge of the bottom of the chassis.

3. The chassis of claim 2, wherein the at least one rise comprises a plurality of rises formed in the outer surface of the bottom of the chassis.

4. The chassis of claim 3, wherein the plurality of spaced-apart notches are formed in an edge of a first layer of the bottom of the chassis, and wherein the plurality of rises are formed in an outer surface of a second layer of the bottom of the chassis.

5. The chassis of claim 4, wherein each of the plurality of rises is substantially centered within a respective one of the plurality of spaced-apart notches to permit fluid to concentrate in regions surrounding the plurality of rises and drip from the chassis.

6. The chassis of claim 1, wherein the at least one notch creates a plurality of bends along the edge of the bottom of the chassis to increase a distance that the flow of fluid traverses.

7. The chassis of claim 6, wherein the plurality of bends comprises at least six bends along the edge of the bottom of the chassis.

8. A method of mitigating fluid wicking in a chassis of an information handling system cooled by a liquid cooling subassembly housed within the chassis, the method comprising:
disrupting a flow of fluid within the chassis with at least one notch formed along an edge of a bottom of the chassis, wherein the fluid comprises coolant leaked from the liquid cooling subassembly and wherein the at least one notch increases a distance the fluid traverses to slow wicking of the fluid;
concentrating at least a portion of the flow of fluid at one or more rises formed in an outer surface of the bottom of the chassis; and
permitting the fluid to drip from regions of the outer surface surrounding the one or more rises to reduce the flow of fluid.

9. The method of claim 8, wherein the at least one notch comprises a plurality of spaced-apart notches formed along the edge of the bottom of the chassis.

10. The method of claim 9, wherein the rise comprises a plurality of rises formed in the outer surface of the bottom of the chassis.

11. The method of claim 10, wherein the plurality of spaced-apart notches are formed in an edge of a first layer of the bottom of the chassis, wherein the plurality of rises are formed in an outer surface of a second layer of the bottom of the chassis, and wherein each of the plurality of rises is approximately centered within a respective one of the plurality of spaced-apart notches.

12. The method of claim 11, wherein the at least one notch creates a plurality of bends along the edge of the first layer to increase a distance that the flow of fluid traverses.

13. The method of claim 12, wherein the plurality of bends comprises at least six bends along the edge of the chassis.

14. An information handling system, comprising:
a wicking prevention chassis;
a liquid-cooling subassembly housed within the wicking prevention chassis;
one or more processing units housed within the wicking prevention chassis; and
a memory communicatively coupled with the one or more processing units via a bus within the wicking prevention chassis,
wherein the wicking prevention chassis includes:
at least one notch formed in an edge of a bottom of the chassis, wherein the notch is configured to disrupt a flow of fluid within the chassis caused by leakage from a liquid cooling subassembly within the chassis and to slow wicking of the fluid; and
at least one rise in an outer surface of the bottom of the chassis, wherein the rise is created by dimpling an opposing surface of the bottom of the chassis and wherein the rise is configured to concentrate at least a portion of the flow of fluid in regions of the outer surface surrounding the rise.

15. The information handling system of claim 14, wherein the at least one notch comprises a plurality of spaced-apart notches formed in the edge of the bottom of the chassis.

16. The information handling system of claim 15, wherein the at least one rise comprises a plurality of rises formed in the outer surface of the bottom of the chassis.

17. The information handling system of claim 16, wherein the plurality of spaced-apart notches are formed in an edge of a first layer of the bottom of the chassis, and wherein the plurality of rises are formed in an outer surface of a second layer of the bottom of the chassis.

18. The information handling system of claim 17, wherein each of the plurality of rises is substantially centered within a respective one of the plurality of spaced-apart notches to permit the fluid to concentrate in regions surrounding the rises and to drip from the chassis.

19. The information handling system of claim 14, wherein the at least one notch creates a plurality of bends along the edge of the bottom of the chassis to increase a distance that the fluid flow traverses.

20. The information handling system of claim 19, wherein the plurality of bends comprises at least six bends along the edge of the chassis.
